(19) United States
(12) Patent Application Publication
(10) Pub. No.: US 2015/0195915 A1
(43) Pub. Date: Jul. 9, 2015

(54) DISPLAY DEVICE AND METHOD FOR MANUFACTURING THE SAME

(71) Applicant: SAMSUNG DISPLAY CO., LTD., Yongin-City (KR)

(72) Inventor: Jun Namkung, Yongyeon-ro (KR)

(21) Appl. No.: 14/302,263

(22) Filed: Jun. 11, 2014

(30) Foreign Application Priority Data
Jan. 6, 2014 (KR) 10-2014-0001198

(51) Int. Cl. H05K 1/18; H05K 3/00; B32B 38/10; H05K 1/02; B32B 37/24

(52) U.S. Cl. CPC H05K 1/185; H05K 1/028; B32B 37/24; B32B 38/10; H05K 3/00; H05K 2201/0133; H05K 2201/0162; H05K 2201/0191; B32B 2037/243; B32B 2457/202; B32B 2457/206; B32B 2457/20; H05K 2203/06; H05K 2203/02; H05K 2203/0779

(57) ABSTRACT

A flexible display device includes a flexible substrate, a coating layer on one surface of the flexible substrate, a driver circuit on the other surface of the flexible substrate, and a display element on the driver circuit, the coating layer including polymer resin and nano particles dispersed in the polymer resin.

### CROSS-REFERENCE TO RELATED APPLICATION

This application claims priority to and the benefit of Korean Patent Application No. 10-2014-0001198, filed on Jan. 6, 2014, with the Korean Intellectual Property Office, the disclosure of which is incorporated herein in its entirety by reference.

### BACKGROUND

1. Field

Embodiments of the present invention relate to a display device including a flexible substrate provided with a coating layer thereon, and a method for manufacturing the same.

2. Description of the Related Art

Recently, flexible display device which can be bent has been developed. The flexible display device can be used (utilized) in a folded or curved state, and can be applied to various areas. In a flexible display device, display elements are arranged on a flexible substrate. There are various kinds of display elements such as, for example, an organic light emitting diode (OLED), a liquid crystal display (LCD) device, or an electrophoretic display device (EPD). Among these, the OLED is drawing attention as a display element for a flexible display device because it can be manufactured to have a thin film laminated structure, which in turn imparts flexibility.

When manufacturing a display device with a flexible substrate, a driver circuit, such as a thin film transistor (TFT), is first disposed on the flexible substrate and a display element is then formed on the driver circuit. However, there are many difficulties in manufacturing the flexible display device with a flexible substrate using (utilizing) manufacturing facilities which are suitably designed to manufacture a display device with a typical glass substrate, in terms of manufacturing processes.

In order to solve this problem, when manufacturing the flexible display device using (utilizing) existing facilities, a flexible substrate is disposed on a carrier substrate such as a glass substrate, TFTs are formed on the flexible substrate, display elements are formed on the TFTs, and finally the carrier substrate is removed from the flexible substrate.

Since the flexible substrate which is made of plastic etc. has poor gas-proof/water-proof performance compared to glass substrates, the flexible substrate and the display element need to be protected from moisture or external gas such as oxygen after the carrier substrate is removed from the flexible substrate.

The foregoing is intended merely to aid in the understanding of the background of the present invention, and is not intended to mean that the present invention falls within the purview of the related art that is already known to those skilled in the art.

### SUMMARY

Aspects of embodiments of the present invention are directed toward a flexible display device in which a flexible substrate is protected by a coating layer.

Further, aspects of embodiments of the present invention are directed toward a flexible display device in which a flexible substrate and a display element are protected by a coating layer which is formed of polymer resin containing nano particles therein.

Further, aspects of embodiments of the present invention are directed toward a method for manufacturing a flexible display device in which a flexible substrate is protected by polymer resin containing nano particles therein.

According to an embodiment of the present invention, a flexible display device includes a flexible substrate; a coating layer on one surface of the flexible substrate; a driver circuit on another surface of the flexible substrate facing away from the one surface of the flexible substrate; and a display element on the driver circuit, wherein the coating layer includes a polymer resin and nano particles dispersed in the polymer resin.

The polymer resin may include at least one selected from acrylic resin, urethane resin, urethane acrylate resin, silicone resin, rubber resin, and epoxy resin.

The nano particle may include at least one selected from SiO₂, Al₂O₃, BaSO₄, BiOCl, CaCO₃, FePO₄, Li₂MoO₄, MoO₃, WO₃, Y₂Eu₂O₃, ZnO, graphite oxide, and graphene oxide.

The nano particle may have an average particle size of about 1 nm to about 1000 nm.

The nano particle may be 10 to 200 parts by weight with respect to 100 parts by weight of the polymer resin.

The coating layer may have a thickness of about 10 μm to about 500 μm.

The display element may be an organic light emitting diode, a liquid crystal display device, or an electrophoretic display device.

The flexible display device may further include a thin film encapsulation layer on the display element.

A neutral plane of the display element may be positioned in an organic light emitting diode or the driver circuit.

According to an embodiment of the present invention, a method for manufacturing a flexible display device includes preparing a carrier substrate; disposing a flexible substrate on the carrier substrate; disposing (e.g., arranging) a display element on the flexible substrate; separating the carrier substrate from the flexible substrate; and forming a coating layer on a surface of the flexible substrate.

The coating layer may be formed of a polymer resin containing nano particles.

The polymer resin may include at least one selected from acrylic resin, urethane resin, urethane acrylate resin, silicone resin, rubber resin, and epoxy resin.

The nano particle may include at least one selected from SiO₂, Al₂O₃, BaSO₄, BiOCl, CaCO₃, FePO₄, Li₂MoO₄, MoO₃, WO₃, Y₂Eu₂O₃, ZnO, graphite oxide, and graphene oxide.

The nano particle may have an average particle size of about 1 nm to about 1000 nm.

The nano particle may be 10 to 200 parts by weight with respect to 100 parts by weight of the polymer resin.

The coating layer may have a thickness of about 10 μm to about 500 μm.

The display element may be an organic light emitting diode, a liquid crystal display device, or an electrophoretic display device.

The method may further include forming a thin film encapsulation layer on the display element after the disposing of the display element and before the separating of the carrier substrate from the flexible substrate.

According to an embodiment of the present invention, a flexible display device includes a flexible substrate; a coating layer on a surface of the flexible substrate; a driver circuit on the coating layer; and a display element on the driver circuit, wherein the coating layer includes a polymer resin and nano particles dispersed in the polymer resin.

The flexible display device may further include a barrier layer between the coating layer and the driver circuit.

According to embodiments of the present invention, a flexible display device includes a coating layer made of polymer resin containing nano particles, thereby reducing or preventing gas or moisture from infiltrating into the flexible display device through a flexible substrate. As a result, display elements of the flexible display device can be effectively protected.

Further, according to embodiments of the present invention, the position of a neutral plane NP that is formed by a bending moment can be changed by adjusting the thickness of the coating layer made of polymer resin so that stress occurring in the flexible display device can be reduced.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

The above and other objects, features and other enhancements of the present invention will be more clearly understood from the following detailed description when taken in conjunction with the accompanying drawings, in which:

FIG. 1 is a cross-sectional view illustrating a flexible display device according to one embodiment;

FIG. 2 is a plan view illustrating an internal structure of the flexible display device illustrated in FIG. 1;

FIG. 3 is a cross-sectional view taken along the line I-I′ in FIG. 2;

FIG. 4 is a cross-sectional view illustrating the flexible display device of FIG. 1 which is in a state of being bent;

FIGS. 5A to 5F are cross-sectional views illustrating sequential manufacturing processes of the flexible display device illustrated in FIG. 1;

FIG. 6 is a cross-sectional view illustrating a flexible display device according to another embodiment; and

FIG. 7 is a cross-sectional view illustrating a flexible display device according to yet another embodiment.

### DETAILED DESCRIPTION

Aspects of the present invention will be described with reference to embodiments illustrated in the drawings. However, the embodiments disclosed in the drawings and the detailed description are not intended to limit the scope of the present invention. The accompanying drawings are selected only for illustrative purposes of the embodiments of the present invention.

Each element and its shape may be schematically or exaggeratedly illustrated to help understanding of the invention. Some elements provided for a real product may not be illustrated or may be omitted in the drawings or the description. The drawings should be construed to help the understanding of the invention.

It will be understood that when an element is referred to as being “on”, “over”, “disposed on”, “disposed over”, “deposited on”, or “deposited over” another element, it can be directly on or over the other element or intervening elements may also be present. Further, the use of “may” when describing embodiments of the present invention refers to “one or more embodiments of the present invention.”

Embodiments of the present invention are described below.

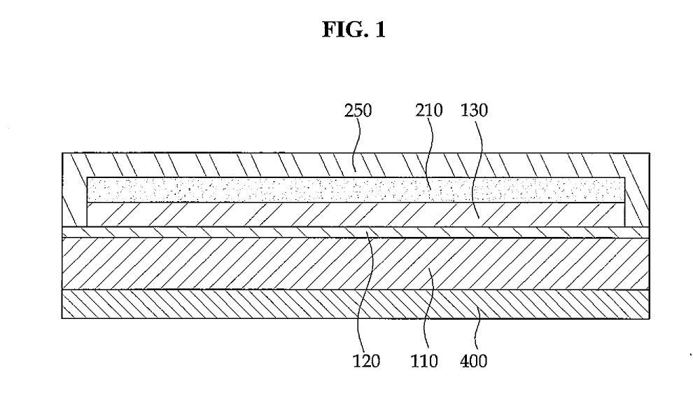

As illustrated in FIG. 1, a flexible display device according to one embodiment includes a flexible substrate 110, a coating layer 400 on one surface of the flexible substrate 110, a driver circuit 130 on the other surface of the flexible substrate 110 (facing away from the one surface having the coating layer 400 thereon), and display elements 210 on the driver circuit 130. Herein, the one surface of the flexible substrate 110 is a surface provided with the coating layer 400 and the other surface of the flexible substrate 110 is a surface provided with the display elements 210. However, the one surface may be a surface provided with the display elements 210 and the other surface may be a surface provided with the coating layer 400.

The flexible substrate 110 may be made of a flexible material. For example, the flexible substrate 110 may be made of plastic. In one embodiment, the flexible substrate 110 may be made of any one material selected from Kapton®, polyethersulphone (PES), polycarbonate (PC), polyimide (PI), polyethyleneterephthalate (PET), polyethylenenaphthalate (PEN), polyacrylate (PAR), and fiber reinforced plastic (FRP). Among these, polyimide (PI) is an especially suitable material for the flexible substrate 110 which will undergo thermal processes because polyimide is excellent in thermal resistance.

The flexible substrate 110 has a thickness of about 5 μm to about 200 μm. In the case where the thickness of the flexible substrate 110 is less than 5 μm, the flexible substrate 110 is difficult to stably support the display element 210. On the other hand, in the case where the thickness of the flexible substrate 110 is 200 μm or greater, the flexible substrate 110 has poor flexibility.

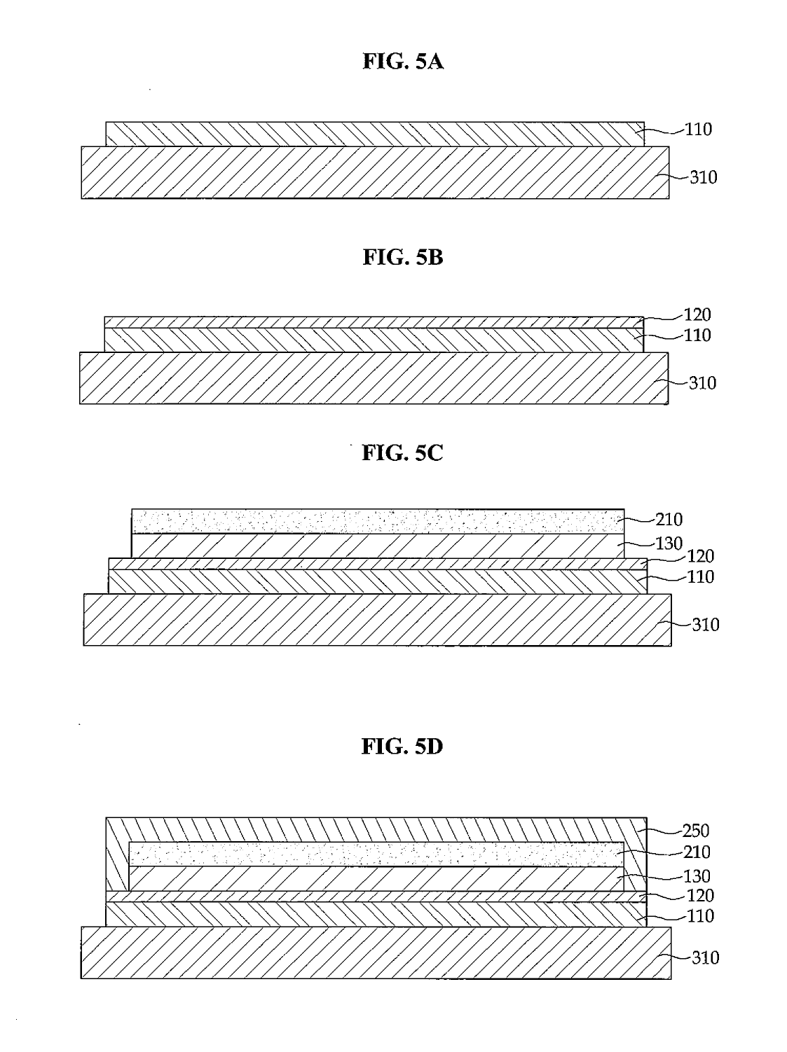

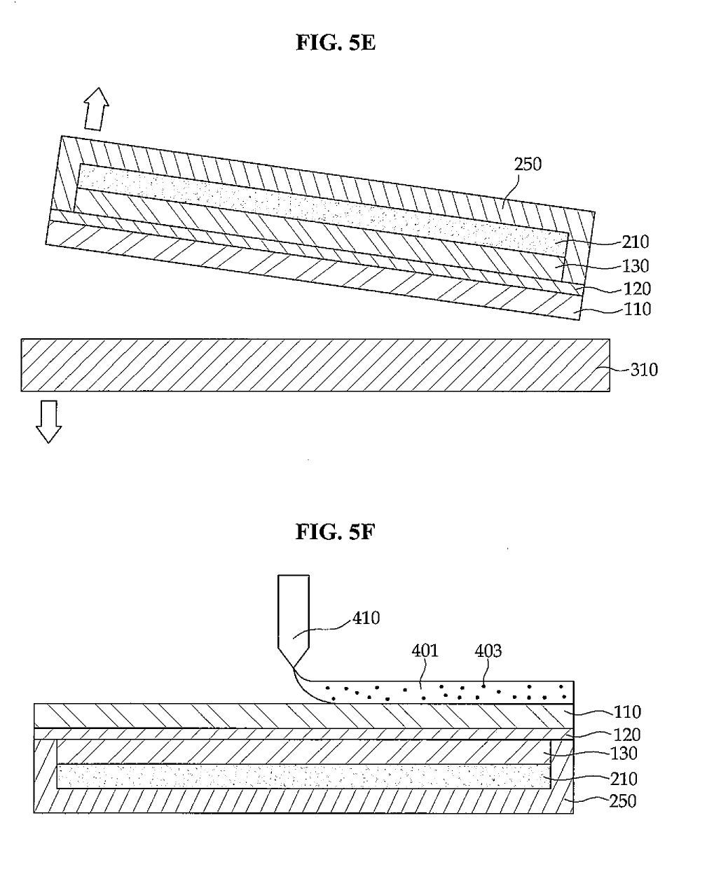

The flexible substrate 110 has a coefficient of thermal expansion (CTE) of about 3 ppm/° C. to about 10 ppm/° C. In the case where the CTE of the flexible substrate 110 is lower than 3 ppm/° C. or higher than 10 ppm/° C., a difference in CTE between a carrier substrate (refer to 310 in FIGS. 5A to 5F) and the flexible substrate 110 excessively increases while the flexible display device is being manufactured. If the difference in CTE increases in this way, the flexible substrate 110 and the carrier substrate 310 are likely to be separated from each other during the manufacturing process of the flexible display device.

The coating layer 400 is disposed on the one surface of the flexible substrate 110 which is the opposite surface to the surface having the display elements 210 disposed thereon.

The coating layer 400 includes polymer resin 401 and nano particles 403 dispersed in the polymer resin 401. The polymer resin 401 imparts stable adhesion between the coating layer 400 and the flexible substrate 110, and the nano particles 403 function to reduce or prevent infiltration of gas or moisture.

Examples of the polymer resin 401 used (utilized) for the coating layer 400 may include acrylic resin, urethane resin, urethane acrylate resin, silicone resin, rubber resin, and epoxy resin. The enumerated resins may be used (utilized) alone (singularly) or in combination of two or more kinds.

The nano particles 403 are dispersed in the polymer resin 401. The nano particles 403 act as a barrier by reacting with gas or moisture which infiltrates into the coating layer 400, thereby reducing or preventing the gas or moisture from progressing into the display elements 210.

The nano particles 403 may include metallic oxide, inorganic substances, or carbon oxide. Examples of the nano particles 403 may include SiO₂, Al₂O₃, BaSO₄, BiOCl, CaCO₃, FePO₄, Li₂MoO₄, MoO₃, WO₃, Y₂Eu₂O₃, ZnO, graphite oxide, and graphene oxide. These can be used singularly or in combination of two or more kinds.

The nano particles 403 have an average particle size of about 1 nm to about 1000 nm. In the case where the average particle size of the nano particles is 1 nm or smaller, the nano particles cannot be easily produced, and may not be uniformly dispersed in the polymer resin because the nano particles tend to agglomerate together in the process of producing a composition for the coating layer. In the case where the average particle size of the nano particles is larger than 1000 nm, because the nano particles are likely to press on a substrate or protrude from a surface of the polymer resin, the coating layer 400 cannot be formed to be thin and uniform.

The coating layer 400 may have a thickness of about 10 μm to about 500 μm. In the case where the thickness of the coating layer 400 is less than 10 μm, the coating layer 400 cannot reliably reduce or prevent infiltration of moisture or external gas such as oxygen. On the other hand, in the case where the thickness of the coating layer 400 exceeds 500 μm, this thickness impedes slimness of a display device. However, when the coating layer 400 is applied to a large display device, the coating layer 400 may have a thickness of 500 μm or thicker.

The coating layer 400 may include 100 parts by weight of the polymer resin 401, and 10 to 200 parts by weight of the nano particles 403 with respect to 100 parts by weight of the polymer resin 401. In the case where the content of the nano particles 403 is lower than 10 parts by weight, the coating layer 400 cannot reliably reduce or prevent infiltration of moisture or external gas. On the contrary, in the case where the content of the nano particles 403 exceeds 200 parts by weight, it is difficult to form the coating layer 400.

Table 1 shows the water vapor transmission rate (WVTR) of a coating layer 400 (in which SiO₂ with an average particle size of 50 nm is dispersed). Here, the WVTR varies depending on the content of SiO₂. Herein, the thickness of the coating layer 400 is 100 μm, and the content of SiO₂ is relatively expressed by parts by weight with respect to 100 parts by weight of acrylic resin.

TABLE 1

| Content of SiO₂ | |
|---|---|
| [Parts by Weight] | WVTR(g/m² day) |
| 0 | 3.90 |
| 10 | 3.56 |
| 25 | 1.80 |
| 50 | 0.90 |
| 100 | 0.24 |

It is found from Table 1 that the WVTR dramatically decreases as the content of the nano particles (dispersed in the acrylic resin) increases. The WVTR of a comparable PET film (thickness: 100 μm) used (utilized) to protect a flexible substrate of a comparable flexible display device is about 24.4. On the other hand, the coating layer 400 according to an embodiment of the present invention exhibits an excellent performance of water vapor transmission prevention, compared to the comparable PET film used (utilized) to protect the comparable flexible substrate.

The display element 210 may be an organic light emitting diode (OLED), a liquid crystal display (LCD) device, or an electrophoretic display (EPD) device. These devices each have in common a thin film transistor (TFT). Here, several cycles of thin film forming processing are performed to manufacture a flexible display device.

Hereinafter, the structure of a flexible display device including OLEDs as the display elements 210 is described with reference to FIG. 1.

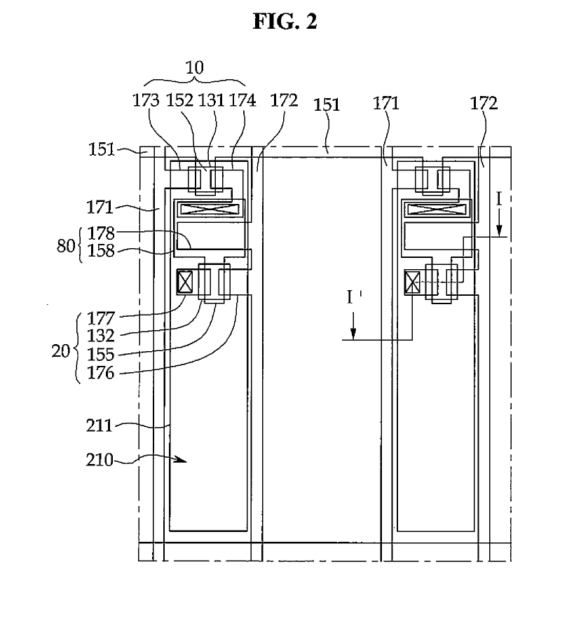

With reference to FIG. 1, the driver circuit 130 configured to drive the display elements 210 is arranged on the flexible substrate 110. The driver circuit 130 includes TFTs 10 and 20 (refer to FIG. 2) and drives the OLEDs 210 (serving as the display elements). That is, the OLEDs 210 (serving as the display elements) emit light according to a driving signal received from the driver circuit 130 so that an image is displayed.

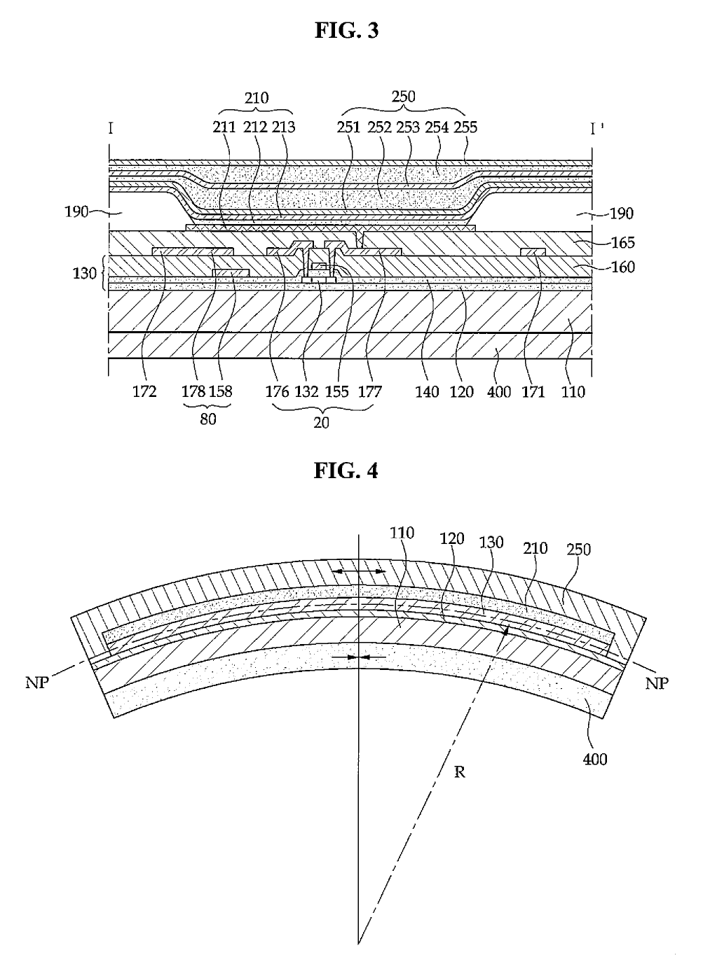

Although the detailed structures of the driver circuit 130 and the OLED 210 are illustrated in FIGS. 2 and 3, embodiments of the present invention are not limited to FIGS. 2 and 3. The driver circuit 130 and the OLED 210 may be embodied in many different forms within a range in which those skilled in the art can easily excogitate.

Hereinafter, the internal structure of the flexible display device including the OLED 210 will be described in more detail with reference to FIGS. 2 and 3. FIG. 2 is a plan view of the structure of a pixel, and FIG. 3 is a cross-sectional view taken along the line I-I′ in FIG. 2.

Although FIGS. 2 and 3 illustrate an active-matrix OLED display with a 2Tr-1 Cap structure, which includes two TFTs (10 and 20) and a capacitor (80) in one pixel, embodiments of the present invention are not limited thereto. A flexible display device according to one embodiment may include three or more TFTs and two or more capacitors in one pixel, and may further include wires. The flexible display device according to one embodiment may have many different structures. Herein, the term “pixel” refers to the smallest unit for displaying an image, and the pixel is arranged in a pixel area. The flexible display device displays an image using (utilizing) a plurality of pixels.

As illustrated in FIGS. 2 and 3, every pixel includes a switching TFT 10, a driving TFT 20, a capacitor 80, and an OLED 210. The configuration including the switching TFT 10, the driving TFT 20, and the capacitor 80 is called the driver circuit 130. The driver circuit 130 further includes a gate line 151 arranged along one direction, a data line 171 insulated from and intersecting (crossing) the gate line 151, and a shared power supply line 172. One pixel area is defined by the gate line 151, the data line 171, and the shared power supply line 172, but may be differently defined. For example, the pixel area may be defined by a black matrix or a pixel defining layer (PDL).

The OLED 210 includes a first electrode 211 serving as an anode, a second electrode 213 serving as a cathode, and a light emitting layer 212 disposed between the first electrode 211 and the second electrode 213. However, embodiments of the present invention are not limited to this structure. The first electrode 211 may function as a cathode, and the second electrode 213 may function as an anode.

The flexible display device may be a top emission flexible display device, a bottom emission flexible display device, or a dual emission flexible display device.

In the case of the top emission flexible display device, the first electrode 211 is formed of a reflective layer and the second electrode 213 is formed of a translucent layer. On the other hand, in the case of the bottom emission flexible display device, the first electrode 211 is formed of a translucent layer and the second electrode 213 is formed of a reflective film. Further, in the case of the dual emission flexible display device, both of the first electrode 211 and the second electrode 213 may be formed of a transparent layer or a translucent layer.

The reflective layer or translucent layer may be made of at least one metal selected from magnesium (Mg), silver (Ag), gold (Au), calcium (Ca), lithium (Li), chrome (Cr), and aluminum (Al); and/or a metal alloy of those metals. In this case, whether a layer is a reflective layer or a translucent layer depends on the thickness of the layer. Generally, the translucent layer has a thickness of 200 nm or less. As the thickness of the translucent layer decreases, the transmittance of light passing through the layer increases. On the contrary, as the thickness of the translucent layer increases, the transmittance of light passing through the layer decreases.

The transparent layer is made of Indium Tin Oxide (ITO), Indium Zinc Oxide (IZO), zinc oxide (ZnO), or indium oxide (In₂O₃).

At least one selected from a hole injection layer (HIL) and a hole transporting layer (HTL) may be disposed between the first electrode 211 and the light emitting layer 212. At least one selected from an electron transporting layer (ETL) and an electron injection layer (EIL) may be disposed between the light emitting layer 212 and the second electrode 213.

The OLED 210 injects, holes and electrons into the light emitting layer 212 through the first electrode 211 and the second electrode 213. When exitons generated by combination of the injected holes and electrons fall from an excited state to a ground state, light emission is performed by the OLED 210.

The capacitor 80 includes a pair of capacitor plates 158 and 178 with an interlayer insulating layer 160 interposed therebetween. The interlayer insulating layer 160 is a dielectric material. Capacitance of the capacitor 80 is determined by electric charges stored in the capacitor 80 and voltage between the pair of capacitor plates 158 and 178.

The switching TFT 10 includes a switching semiconductor layer 131, a switching gate electrode 152, a switching source electrode 173, and a switching drain electrode 174. The driving TFT 20 includes a driving semiconductor layer 132, a driving gate electrode 155, a driving source electrode 176, and a driving drain electrode 177. In addition, a gate insulating layer 140 is provided to insulate the gate electrodes 152 and 155 from the semiconductor layers 131 and 132.

The switching TFT 10 functions as a switching device which selects a pixel to perform light emission. The switching gate electrode 152 is connected to the gate line 151. The switching source electrode 173 is connected to the data line 171. The switching drain electrode 174 is spaced apart from the switching source electrode 173 and connected to one capacitor plate 158.

The driving TFT 20 applies driving power to the first electrode 211 (serving as a pixel electrode), which allows the light emitting layer 212 of the OLED 210 in the selected pixel to emit light. The driving gate electrode 155 is connected to the capacitor plate 158 (connected to the switching drain electrode 174). The driving source electrode 176 and the other capacitor plate 178 are connected to the shared power supply line 172. A planarization layer 165 is disposed on the TFTs 10 and 20, and the driving drain electrode 177 is connected to the pixel electrode 211 of the OLED 210 through a contact hole of the planarization layer 165.

With the above-described structure, the switching TFT 10 is operated by a gate voltage applied to the gate line 151, and functions to transmit a data voltage (applied to the data line 171) to the driving TFT 20. A voltage equivalent to a differential between a common voltage (applied to the driving TFT 20 from the shared power supply line 172) and the data voltage (transmitted from the switching TFT 10) is stored in the capacitor 80, and a current corresponding to the voltage stored in the capacitor 80 flows to the OLED 210 through the driving TFT 20, so that the OLED 210 emits light.

The flexible display device further includes a thin film encapsulation layer 250, which is disposed on the flexible substrate 110 and configured to cover the display elements 210; and a barrier layer 120, which is disposed between the display elements 210 and the flexible substrate 110.

The thin film encapsulation layer 250 includes one or more inorganic layers 251, 253, and 255; and one or more organic layers 252 and 254. The thin film encapsulation layer 250 has a laminated structure in which the inorganic layers (251, 253, and 255) and the organic layers (252 and 254) are alternately laminated. In this case, the inorganic layer 251 is the lowermost layer. That is, the inorganic layer 251 is disposed to be the closest to the OLED 210. Although the thin film encapsulation layer 250 includes three inorganic layers (251, 253, and 255) and two organic layers (252 and 254) in FIG. 3, embodiments of the present invention are not limited to this structure.

The inorganic layers 251, 253, and 255 are formed of one or more inorganic substances selected from Al₂O₃, TiO₂, ZrO, SiO₂, AlON, AlN, SiON, Si₃N₄, ZnO, and Ta₂O₅. The inorganic layers 251, 253, and 255 are formed by using (utilizing) a chemical vapor deposition (CVD) method or an atomic layer deposition (ALD) method. However, embodiments of the present invention are not limited to these methods. The inorganic layers 251, 253, and 255 can be formed by using (utilizing) many different suitable methods which are known to those skilled in the art.

The organic layers 252 and 254 are made of a polymer material. Examples of the polymer material include acrylic resin, epoxy resin, polyimide, polyethylene, and the like. The organic layers 252 and 254 are formed through a thermal deposition process. The thermal deposition process for forming the organic layers 252 and 254 is performed at a temperature at which the OLED 210 is not likely to be damaged. However, embodiments of the present invention are not limited thereto, and the organic layers 252 and 254 can be formed by using (utilizing) many different suitable methods known to those skilled in the art.

The inorganic layers 251, 253, and 255, which have high density, suppress the infiltration of moisture or oxygen. The infiltration of moisture or oxygen into the OLED 210 is reduced or prevented by the inorganic layers 251, 253, and 255.

Moisture or oxygen passed through the inorganic layers 251, 253, and 255 is intercepted by the organic layers 252 and 254. The organic layers 252 and 254 are relatively poor in terms of water vapor transmission prevention effects, compared to the inorganic layers 251, 253, and 255. However, the organic layers 252 and 254 function not only as a water vapor transmission preventing layer but also as a buffer layer which reduces stress between the neighboring inorganic layers 251, 253, and 255 (such as stress between the inorganic layers 251 and 253, and/or stress between the inorganic layers 253 and 255) caused by bending of the flexible display device. To be specific, in the case where each of the inorganic layers 251, 253, and 252 is sequentially formed directly on one of the respective inorganic layers 251, 253, and 255 without the intervening organic layers 242 and 254, stress occurs between the neighboring inorganic layers 251, 253, and 255 when the flexible display device is bent, and the stress causes damage to the inorganic layers 251, 253, and 255. As a result, the effect of the thin film encapsulation layer 250 as the water vapor transmission preventing layer is deteriorated. Further, since the organic layers 252 and 254 have planarization properties, the top surface of the thin film encapsulation layer 250 can be planarized.

The thin film encapsulation layer 250 may have a thickness of 10 μm or less. Accordingly, the flexible display device can be formed to be small in its total thickness. With the thin film encapsulation layer 250 included in the flexible display device, flexibility of the flexible display device can be increased.

The barrier layer 120 may be formed of one or more layers selected from various suitable inorganic and organic layers.

Both of the thin film encapsulation layer 250 and the barrier layer 120, which are formed in the manner described above, reduce or prevent the infiltration of unnecessary components such as moisture into the OLED 210.

With this configuration, it is possible to effectively reduce or prevent faults in the flexible display device according to one embodiment of the present invention.

FIG. 4 shows a bent state of the flexible display device of FIG. 1.

When the flexible display device is bent by a bending moment, a neutral plane NP is formed. The neutral plane NP is a plane which does not contract or expand but maintains its original length when a member is bent under a certain force. When taking the neutral plane NP, on which stress is not exerted at the time of bending, as a reference point, compressive stress occurs in an area nearer (towards the center of the bent curvature) than the neutral plane NP, and tensile stress occurs in an area farther than the neutral plane NP.

In the case where the flexible display device is used (utilized) in a bent state, the OLED 210 and the driver circuit 130 receive stress and the thin film encapsulation layer 250 also receives stress. In this case, the stress applied to the flexible display device increases as the distance from the neutral plane NP increases.

When repetitive stress or intensive stress which exceeds breaking strength is applied to the flexible display device, devices such as the TFTs 10 and 20 formed in the flexible display device are damaged, or a conductive wire is likely to be disconnected. If the thin film encapsulation layer 250 is damaged due to the stress, moisture is likely to infiltrate into the thin film encapsulation layer 250, thereby causing damage to the OLED 210 and the driver circuit 130.

Since the thickness of the coating layer formed through the coating process can be relatively easily adjusted, compared to the thickness of a film member, the neutral plane NP can be positioned in the OLED 210, the driver circuit 130, or the vicinity of the OLED 210 or the driver circuit 130 of the flexible display device by adjusting the thickness of the coating layer 400. Accordingly, the stress applied to the OLED 210 and the driver circuit 130 can be reduced and damage to the OLED 210 and driver circuit 130 can be reduced or prevented even when the flexible display device is bent.

In the case of a flat plate member made up of one component, the neutral plane NP is positioned on a central (middle) plane in a thickness direction of the flat plate member. In the case of a flat plate member made up of many different components, the neutral plane NP is not necessarily positioned on a central plane in the thickness direction of the flat plate member. When the components of the flat plate member do not greatly differ in physical properties, the neutral plane NP is positioned in the vicinity of a central plane in the thickness of the flat plate member.

According to an embodiment of the present invention, with adjustment of the thickness of the coating layer 400, the neutral plane NP can be positioned in the vicinity of the thin film encapsulation layer 250. Table 2 shows stress ratios applied to the outermost layer according to the thickness of the coating layer 400 when the flexible display device is bent as illustrated in FIG. 4. The outermost layer is an outermost inorganic layer 255 of the thin film encapsulation layer 250 and has a radius of curvature R of 2 mm. As the outermost inorganic layer 255 of the thin film encapsulation layer 250 is positioned outside the neutral plane NP, the outermost inorganic layer 255 is subject to a tensile stress (e.g., most tensile stress). The stress ratio means a ratio of stress applied to the inorganic layer 255 to the total stress applied to the flexible display device when the flexible display device is bent.

TABLE 2

| Thickness of Coating Layer | Stress Ratio That Inorganic Layer 255 |
|---|---|
| (400) [μm] | Receives [%] |
| 100 | 1.13 |
| 80 | 0.88 |
| 60 | 0.65 |
| 40 | 0.42 |
| 20 | 0.22 |

It is evident in Table 2 that as the thickness of the coating layer 400 decreases, the neutral plane NP moves toward the outermost inorganic layer 255 of the thin film encapsulation layer 250, and the stress applied to the outermost inorganic layer 255 decreases. The outermost inorganic layer 255 of the thin film encapsulation layer 250 is an important layer to reduce or prevent infiltration of moisture or gas into the display element 210. When the stress applied to the outermost inorganic layer 255 of the thin film encapsulation layer 250 is reduced, the outermost inorganic layer 255 can be free from a risk of damage so that the display element 210 can be effectively protected.

Hereinafter, a method for manufacturing the flexible display device illustrated in FIG. 1 will be described with reference to FIGS. 5A to 5F.

First, a flexible substrate 110 is arranged on a carrier substrate 310 (refer to FIG. 5A).

A glass substrate is used (utilized) as the carrier substrate 310.

The flexible substrate 110 is formed of a plastic material which is excellent in thermal resistance and durability. However, the flexible substrate 110 made of a plastic material is likely to bend or elongate while heat is applied to the flexible substrate 110. Accordingly, it is difficult to precisely form thin film patterns such as electrodes and conductive wires on the flexible substrate 110. In order to solve this problem, the flexible substrate 110 is arranged on the carrier substrate 310 and then the thin film patterns are formed.

As a method of arranging the flexible substrate 110 on the carrier substrate 310, there is a method of forming a plastic substrate by coating a polymer material for a flexible substrate on the carrier substrate 310 and then curing the polymer material. For example, the polymer material, e.g., polyimide, is coated on the entire surface of the carrier substrate 310 by using (utilizing) a slit coating method, a screen printing method, a spin coating method, or a bar coating method to form a polymer material layer. After that, the polymer material layer is cured by a curing apparatus so that the flexible substrate 110 made of polyimide can be arranged on the carrier substrate 310.

The flexible substrate 110 may have a thickness of about 5 μm to about 200 μm in consideration of manufacturing conditions or flexibility of the flexible substrate 110.

Then, a barrier layer 120 is disposed on the flexible substrate 110 (refer to FIG. 5B).

The barrier layer 120 reduces or prevents moisture or gas from infiltrating into the flexible substrate 110. For example, the barrier layer 120 can be formed by depositing an inorganic insulating material such as silicon oxide (SiO₂) or silicon nitride (SiNₓ) on the entire surface of the flexible substrate 110 made of polyimide.

A driver circuit 130 and an OLED 210 serving as a display element are formed on the barrier layer 120 (refer to FIG. 5C).

A thin film encapsulation layer 250 is formed on the flexible substrate 110 so as to cover the OLED 210 and the driver circuit 130 (refer to FIG. 5D).

Then, the carrier substrate 310 is separated from the flexible substrate 110 (refer to FIG. 5E). For example, the separation of the carrier substrate 310 from the flexible substrate 110 is performed by irradiating the carrier substrate 310 with laser beams. An excimer laser may be used (utilized) as the laser beams. The laser beams pass through the carrier substrate 310 so that the carrier substrate 310 and the flexible substrate 110 (which is made of polyimide) can be separated from each other.

A coating layer is formed on the flexible substrate 110 from which the carrier substrate 310 is removed (refer to FIG. 5F). The coating layer includes polymer resin 401 and nano particles 403 dispersed in the polymer resin 401.

For example, a coating composition including the polymer resin 401 and the nano particles 403 is coated on one surface of the flexible substrate 110 and cured to form the coating layer. The coating composition is coated by using (utilizing) a suitable coating method, such as spin coating or slit coating. When the slit coating is used (utilized), a slit nozzle 410 with a width of about 500 mm to about 1600 mm may be used (utilized). The thickness of the coating layer can be adjusted by adjusting the amount of the coating composition discharged from the slit nozzle or the moving speed of the slit nozzle. The moving speed of the slit nozzle may be in a range of about 10 m/s to about 50 m/s.

The coating composition includes monomers and oligomers for the polymer resin, and the nano particles. The coating composition may further include a solvent, a polymerization initiator, a dispersant, a cross-linking agent, a curing agent, or the like. In the case where the coating composition further includes a thermal initiator, the coating composition is cured through heat curing and the stabilized coating layer 400 is formed. In the case where the coating composition further includes a photoinitiator, the coating composition is cured through photocuring and the stabilized coating layer 400 is formed.

The coating composition may have a viscosity of about 50 cSt to about 15000 cSt in terms of coatability and flowability.

The coating layer 400 includes, as the polymer resin, at least one selected from acrylic resin, urethane resin, urethane acrylate resin, silicone resin, rubber resin, and epoxy resin. Accordingly, the coating composition may include monomers or oligomers for forming the polymer resin.

For example, in the case where the coating layer 400 includes acrylic resin, the coating composition may include (Meth)acrylic acid ester monomers with an alkyl group having 1 to 12 carbon atoms, or polar monomers that can be copolymerized with the (Meth)acrylic acid ester monomers.

The nano particles 403 may include at least one selected from SiO₂, Al₂O₃, BaSO₄, BiOCl, CaCO₃, FePO₄, Li₂MoO₄, MoO₃, WO₃, Y₂Eu₂O₃, ZnO, graphite oxide, and graphene oxide. In this case, the nano particles 403 may have an average particle size of 1 nm to 1000 nm.

The coating layer 400 includes 10 to 200 parts by weight of the nano particles with respect to 100 parts by weight of the polymer resin.

In the case where a protective film with an adhesive layer is used (utilized) to protect the flexible substrate 110, it is not easy to freely adjust the thickness of the protective film. However, according to an embodiment of the present invention, the thickness of the coating layer 400 can be easily adjusted to a range from 10 μm to 500 μm.

In the case where the protective film with an adhesive layer is used (utilized) to protect the flexible substrate 110, bubbles which negatively affect visibility may occur in the bonding process of the protective film. The bubbles are likely to be formed in line between the flexible substrate 110 and the protective film, thereby forming bubble lines.

However, in the case where the coating layer is formed on the flexible substrate 110 according to an embodiment of the present invention, bubbles or bubble lines are not formed in a display device.

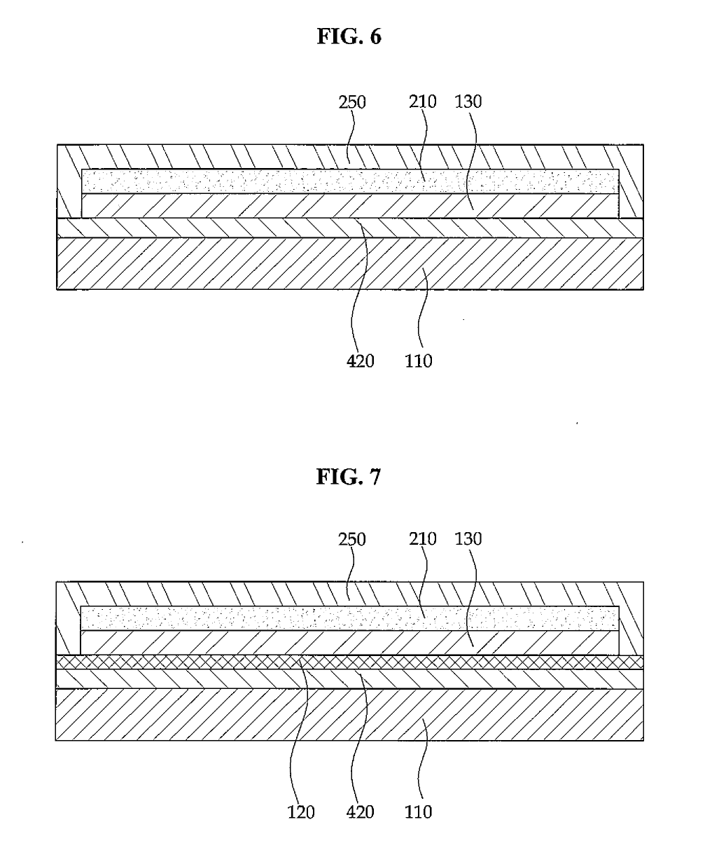

Hereinafter, a flexible display device according to another embodiment of the present invention will be described with reference to FIG. 6.

As illustrated in FIG. 6, a flexible display device includes a flexible substrate 110, a coating layer 420 on one surface of the flexible substrate 110, a driver circuit 130 on the coating layer 420, and display elements 210 on the driver circuit 130. The flexible display device further includes a thin film encapsulation layer 250 which is disposed on the flexible substrate 110 and configured to cover the display elements 210.

The coating layer 420 includes polymer resin and nano particles dispersed in the polymer resin. The polymer resin includes at least one resin selected from acrylic resin, urethane resin, urethane acrylate resin, silicone resin, rubber resin, and epoxy resin. The nano particle includes at least one selected from SiO₂, Al₂O₃, BaSO₄, BiOCl, CaCO₃, FePO₄, Li₂MoO₄, MoO₃, WO₃, Y₂Eu₂O₃, ZnO, graphite oxide, and graphene oxide. The nano particle has an average particle size of about 1 nm to about 1000 nm. The nano particle is 10 to 200 parts by weight with respect to 100 parts by weight of the polymer resin.

The coating layer has a thickness of about 10 μm to about 500 μm.

FIG. 7 illustrates a flexible display device according to yet another embodiment of the present invention. The flexible display device of FIG. 7 includes a flexible substrate 110, a coating layer 420 on one surface of the flexible substrate 110, a barrier layer 120 on the coating layer 420, a driver circuit 130 on the barrier layer 120, and display elements 210 on the driver circuit 130. The flexible display device further includes a thin film encapsulation layer 250 which is formed on the flexible substrate 110 and configured to cover the display elements 210. The flexible display device of FIG. 7 further includes the barrier layer 120, compared to the flexible display device of FIG. 6. Since description about the barrier layer 120 has been previously provided, further description will be omitted for brevity.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims, and equivalents thereof.

What is claimed is:

1. A flexible display device comprising:
a flexible substrate;
a coating layer on one surface of the flexible substrate;
a driver circuit on another surface of the flexible substrate facing away from the one surface of the flexible substrate; and
a display element on the driver circuit,
wherein the coating layer comprises a polymer resin and nano particles dispersed in the polymer resin.

2. The flexible display device of claim 1, wherein the polymer resin comprises at least one selected from acrylic resin, urethane resin, urethane acrylate resin, silicone resin, rubber resin, and epoxy resin.

3. The flexible display device of claim 1, wherein the nano particle comprises at least one selected from SiO₂, Al₂O₃, BaSO₄, BiOCl, CaCO₃, FePO₄, Li₂MoO₄, MoO₃, WO₃, Y₂Eu₂O₃, ZnO, graphite oxide, and graphene oxide.

4. The flexible display device of claim 1, wherein the nano particle has an average particle size of about 1 nm to about 1000 nm.

5. The flexible display device of claim 1, wherein the nano particle is 10 to 200 parts by weight with respect to 100 parts by weight of the polymer resin.

6. The flexible display device of claim 1, wherein the coating layer has a thickness of about 10 μm to about 500 μm.

7. The flexible display device of claim 1, wherein the display element is an organic light emitting diode, a liquid crystal display device, or an electrophoretic display device.

8. The flexible display device of claim 1, further comprising a thin film encapsulation layer on the display element.

9. The flexible display device of claim 8, wherein a neutral plane of the display element is positioned in an organic light emitting diode of the display element or the driver circuit.

10. A method for manufacturing a flexible display device, the method comprising:
preparing a carrier substrate;
disposing a flexible substrate on the carrier substrate;
disposing a display element on the flexible substrate;
separating the carrier substrate from the flexible substrate; and
forming a coating layer on a surface of the flexible substrate.

11. The method of claim 10, wherein the coating layer is formed of a polymer resin containing nano particles.

12. The method of claim 11, wherein the polymer resin comprises at least one selected from acrylic resin, urethane resin, urethane acrylate resin, silicone resin, rubber resin, and epoxy resin.

13. The method of claim 11, wherein the nano particle comprises at least one selected from SiO₂, Al₂O₃, BaSO₄, BiOCl, CaCO₃, FePO₄, Li₂MoO₄, MoO₃, WO₃, Y₂Eu₂O₃, ZnO, graphite oxide, and graphene oxide.

14. The method of claim 11, wherein the nano particle has an average particle size of about 1 nm to about 1000 nm.

15. The method of claim 11, wherein the nano particle is 10 to 200 parts by weight with respect to 100 parts by weight of the polymer resin.

16. The method of claim 11, wherein the coating layer has a thickness of about 10 μm to about 500 μm.

17. The method of claim 10, wherein the display element is an organic light emitting diode, a liquid crystal display device, or an electrophoretic display device.

18. The method of claim 10, further comprising:
forming a thin film encapsulation layer on the display element after the disposing of the display element and before the separating of the carrier substrate from the flexible substrate.

19. A flexible display device comprising:
a flexible substrate;
a coating layer on a surface of the flexible substrate;
a driver circuit on the coating layer; and
a display element on the driver circuit,
wherein the coating layer comprises a polymer resin and nano particles dispersed in the polymer resin.

20. The flexible display device of claim 19, further comprising a barrier layer between the coating layer and the driver circuit.
